(19) United States
(12) Patent Application Publication
(10) Pub. No.: US 2023/0400533 A1
(43) Pub. Date: Dec. 14, 2023

(54) SOFT MAGNETIC FILM IRON CORE AND PREPARATION METHOD THEREFOR AND SENSOR

(71) Applicant: Henan Polytechnic University, Jiaozuo (CN)

(72) Inventor: Hui LV, Henan (CN)

(21) Appl. No.: 17/957,196

(22) Filed: Sep. 30, 2022

Related U.S. Application Data
(63) Continuation of application No. PCT/CN2022/100344, filed on Jun. 22, 2022.

(30) Foreign Application Priority Data
Jun. 9, 2022 (CN) 202210653407.9

(51) Int. Cl. G01R 33/05; C23C 14/16; C23C 14/35; B05D 1/00; C23C 14/20; G03F 7/00; H01F 27/24; H01F 41/02

(52) U.S. Cl. CPC G01R 33/05; C23C 14/165; C23C 14/35; B05D 1/005; C23C 14/205; G03F 7/0035; H01F 27/24; H01F 41/0206

(57) ABSTRACT

A soft magnetic film iron core is provided, including an insulating substrate and a soft magnet. Multiple layers of hollowing-out grid networks stacked vertically are arranged in the soft magnet, and all grid cavities in the hollowing-out grid networks are filled with insulators, such that the micro-morphology of the film iron core is changed, and the film iron core presents a structure of multilayer staggered grid networks as a whole. The soft magnetic film iron core can be processed by the micro-electro-mechanical system (MEMS) process. The proposed preparation method for the soft magnetic film iron core adopts low-cost standard MEMS processes such as ultraviolet (UV) lithography, electroplating, and wet etching, which can realize standardized mass production of the iron core and reduce the processing cost. A sensor using the soft magnetic film iron core as a sensitive element is provided.

### CROSS REFERENCE TO RELATED APPLICATION

This patent application is a continuation application of International Application No. PCT/CN2022/100344, filed on Jun. 22, 2022, which claims the benefit and priority of Chinese Patent Application No. 202210653407.9, filed on Jun. 9, 2022, and designated the U.S., the entire contents of each are hereby incorporated by reference.

### TECHNICAL FIELD

The present disclosure relates to the technical field of iron core preparation, and in particular, to a soft magnetic film iron core and a preparation method therefor, and a sensor.

### BACKGROUND ART

The micro-magnetic fluxgate sensor (hereinafter referred to as the micro fluxgate) is a weak magnetic measurement sensor with excellent comprehensive performance, which has the characteristics of high resolution, excellent temperature stability, and small perming error, and adopts a soft magnetic film iron core as a core sensitive element. The performance of the iron core is a key factor for main indicators such as power consumption, sensitivity, and noise. Soft magnetic film iron cores are developing towards low saturation magnetic induction, high permeability, high Curie temperature, low loss, low coercivity, and low Barkhausen noise.

At present, the film iron cores of micro fluxgates are mostly made of cobalt-based amorphous and permalloy, and are prepared by electroplating or magnetron sputtering. However, the existing electroplated or sputtered film iron cores have high saturation magnetic induction, high coercivity and poor soft magnetic properties, and there is a large gap between the performance of the electroplated or sputtered film iron cores and traditional strips or bulks. The micro-electro-mechanical system (MEMS) process (the “MEMS process”, also known as “MEMS technology”) cannot be used for batch processing on the strip as the iron core, which affects the improvement of the performance of the micro fluxgate. Therefore, how to prepare a high-performance soft magnetic film iron core meeting relative requirements on a silicon substrate with the MEMS process is a major challenge for the development of micro fluxgates.

### SUMMARY

One of the objectives of the present disclosure is to provide a soft magnetic film iron core and a preparation method therefor, so as to solve the problems of high saturation magnetic induction, high coercivity and poor soft magnetic properties of the film iron core in the prior art.

In order to achieve the above objective, the present disclosure provides the following technical solutions:

The present disclosure provides a soft magnetic film iron core, including:
an insulating substrate; and
a soft magnet, arranged on an upper surface of the insulating substrate, and provided with multiple layers of hollowing-out grid networks stacked vertically inside; each layer of the hollowing-out grid network includes several rows and several columns of grid cavities, any two adjacent rows of the grid cavities are staggered, and any two adjacent columns of the grid cavities are staggered; the grid cavities in any two adjacent layers of the hollowing-out grid networks are staggered and complementary; and each of the grid cavities is filled with an insulator.

Optionally, the soft magnet may be a square soft magnet, and any of the grid cavities may be located in the square soft magnet.

Optionally, in the soft magnet, the grid cavities in all odd-numbered layers of the hollowing-out grid networks from bottom to top may have a same distribution structure, and the grid cavities in all even-numbered layers of the hollowing-out grid networks may have a same distribution structure.

Optionally, each of the grid cavities may be a square grid cavity, and any two of the square grid cavities may have a same size.

Optionally, in any odd-numbered layer of the hollowing-out grid network, the grid cavities may be distributed in 7 rows, 9 rows, or 11 rows, and 15 columns, 17 columns, or 19 columns. In any even-numbered layer of the hollowing-out grid network, the grid cavities may be distributed in 7 rows, 9 rows, or 11 rows, and 15 columns, 17 columns, or 19 columns.

The square soft magnet may have a length, width, and height of 2,000-5,000 μm, 1,000-3,000 μm, and 5-50 μm respectively. Any one of the square grid cavities may have a length, width, and height of 40-200 μm, 40-200 μm, and 0.5-3 μm respectively. The grid cavities in each layer of the hollowing-out grid network may have a row spacing and a column spacing of 20-100 μm.

Optionally, in any odd-numbered layer of the hollowing-out grid network, the grid cavities may be distributed in 9 rows and 17 columns. Numbers of the grid cavities in the 9 rows of grid cavities may be 9, 8, 9, 8, 9, 8, 9, 8, and 9 respectively. The grid cavities between any two adjacent rows of the grid cavities may be staggered. In any even-numbered layer of the hollowing-out grid network, the grid cavities may be distributed in 9 rows and 17 columns. Numbers of the grid cavities in the 9 rows of grid cavities may be 8, 9, 8, 9, 8, 9, 8, 9, and 8 respectively. The grid cavities between any two adjacent rows of the grid cavities may be staggered.

The square soft magnet may have a length, width, and height of 4,500 μm, 2,000 μm, and 12 μm respectively. Any one of the square grid cavities may have a length, width, and height of 180 μm, 180 μm, and 2 μm respectively. The grid cavities in each layer of the hollowing-out grid network may have a row spacing and a column spacing both of 60 μm.

Optionally, the soft magnet may be a permalloy soft magnet. The material of the insulator may be polyimide (PI). The insulating substrate may be a silicon wafer substrate with a silicon dioxide insulating layer.

The present disclosure provides a preparation method for the foregoing soft magnetic film iron core, including:
S1, performing sputtering on the upper surface of the insulating substrate to form a Cu seed layer;
S2, spin-coating the PI on the Cu seed layer, subsequently performing pre-imidization treatment and performing ultraviolet (UV) lithography and wet etching treatment by means of a first mask of odd-numbered layer of the iron core to obtain a first layer of PI filled grid, and imidizing the PI;
S3, sputtering around and above the first layer of PI filled grid to form a first layer of the iron core and a permalloy layer between the first layer and a second layer of the iron core;
S4, spin-coating the PI on the permalloy layer between the first layer and a second layer of the iron core, subsequently performing pre-imidization treatment and UV lithography and wet etching treatment by a second mask for even-numbered layer of the iron core to obtain a second layer of PI filled grid, and imidizing the PI;
S5, sputtering around and above the second layer of PI filled grid to form a second layer of iron core and a permalloy layer between the second layer and a third layer of the iron core; and
S6, repeating step S2-step S3-step S4-step S5 or step S2-step S3-step S4-step S5-step S2-step S3 in order for one or more times until the whole soft magnet is prepared.

Optionally, the permalloy layer may be sputtered by a magnetron sputtering process. The permalloy layer between every two adjacent layers of iron cores may have a thickness of 0.5 μm.

The present disclosure further provides a sensor, including the foregoing soft magnetic film iron core.

Optionally, the sensor may be a micro-magnetic fluxgate sensor.

The present disclosure achieves the following technical effects over the prior art:

According to the soft magnetic film iron core provided by the present disclosure, multiple layers of hollowing-out grid networks stacked vertically are arranged in the soft magnet, and all grid cavities in the hollowing-out grid networks are filled with insulators, such that the micro-morphology of the film iron core is changed, and the film iron core presents a structure of multilayer staggered grid networks as a whole. Therefore, it is beneficial to limit the size of the magnetic domain, and promotes uniform saturation of the iron core, thereby effectively reducing saturation magnetic induction and coercivity of the film iron core, and improving its soft magnetic properties.

The soft magnetic film iron core provided by the present disclosure can be processed by the MEMS process, which can effectively reduce saturation magnetic induction and coercivity of the film iron core, and improve its soft magnetic properties.

The foregoing preparation method for the soft magnetic film iron core provided by the present disclosure adopts low-cost MEMS standard processes such as UV lithography, electroplating, and wet etching, which can realize standardized mass production of the iron core and reduce the processing cost without effecting the soft magnetic properties of the iron core.

The present disclosure further provides the sensor using the foregoing soft magnetic film iron core as a sensitive element, which can effectively reduce power consumption and improve sensitivity and reduce noise of the sensor to a certain extent.

The sensor provided by the present disclosure may be a micro-magnetic fluxgate sensor using the soft magnetic film iron core as a sensitive element, which can effectively reduce power consumption and improve sensitivity and reduce noise to a certain extent.

### BRIEF DESCRIPTION OF THE DRAWINGS

FIG. 1 is a top view of a soft magnetic film iron core disclosed in an embodiment of the present disclosure (a schematic diagram showing distribution of a topmost hollowing-out grid network);

FIG. 2 is a cross-sectional view taken along line A-A of FIG. 1;

FIG. 3 is a cross-sectional view taken along line B-B of FIG. 1;

FIG. 4 is a cross-sectional view taken along line C-C of FIG. 3;

FIG. 5 is a schematic diagram of staggered complementary distribution of filled grids formed after an odd-numbered layer and an even-numbered layer are overlapped according to the embodiment of the present disclosure; and

FIG. 6 is a schematic diagram showing a preparation process of the soft magnetic film iron core according to the embodiment of the present disclosure.

Reference Numerals: 1—insulating substrate, 2—Polyimide (PI), and 3—soft magnetic material.

### DETAILED DESCRIPTION OF THE EMBODIMENTS

The technical solutions of the embodiments of the present disclosure are clearly and completely described below with reference to the accompanying drawings. Apparently, the described embodiments are merely a part rather than all of the embodiments of the present disclosure. All other embodiments obtained by those of ordinary skill in the art based on the embodiments of the present disclosure without creative efforts shall fall withe protection scope of the present disclosure.

One objective of some embodiments is to provide a soft magnetic film iron core, so as to solve the problems of high saturation magnetic induction and coercivity and poor soft magnetic properties of the current film iron core.

Another objective of some embodiments is to provide a preparation method for a soft magnetic film iron core.

A yet another objective of some embodiments is to provide a sensor provided with the above soft magnetic film iron core.

To make the above-mentioned objectives, features, and advantages of the present disclosure clearer and more comprehensible, the present disclosure will be further described in detail below in conjunction with the accompanying drawings and specific embodiments.

### Embodiment I

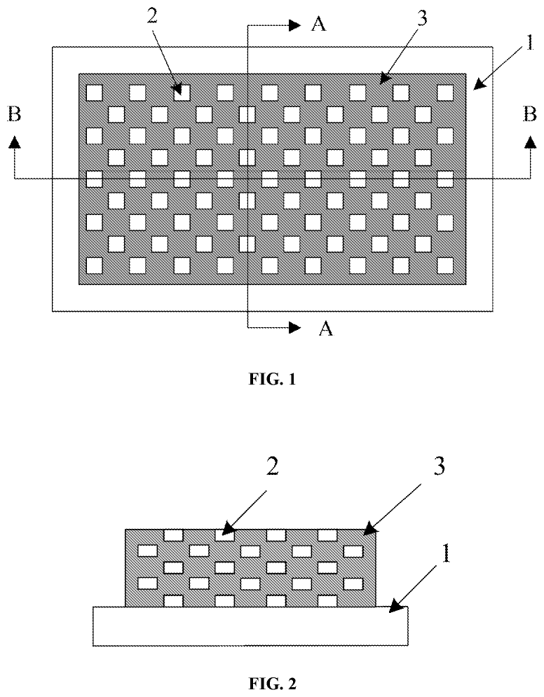

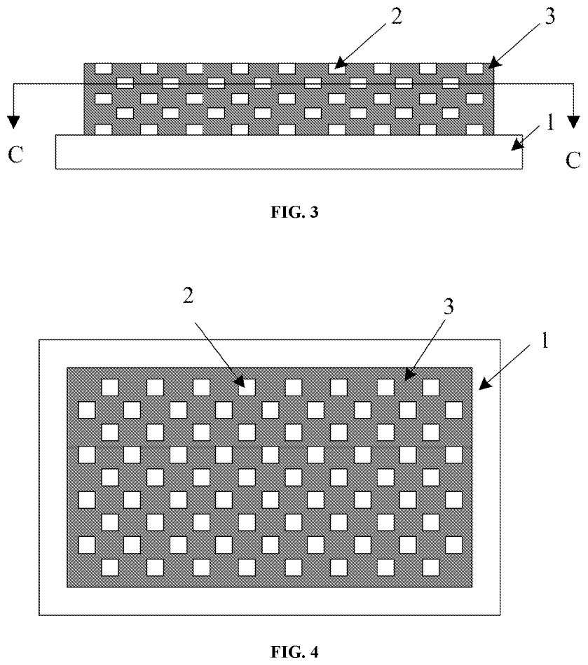

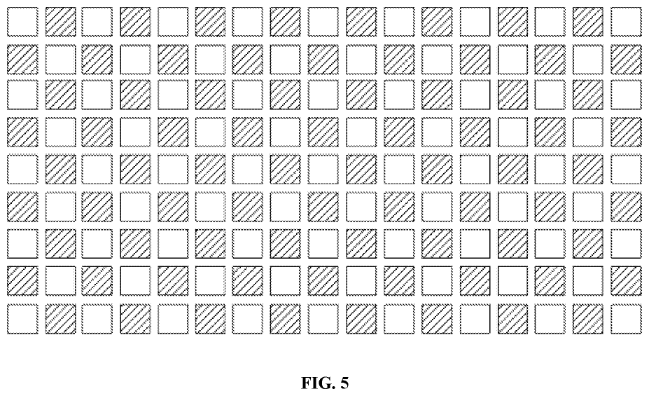

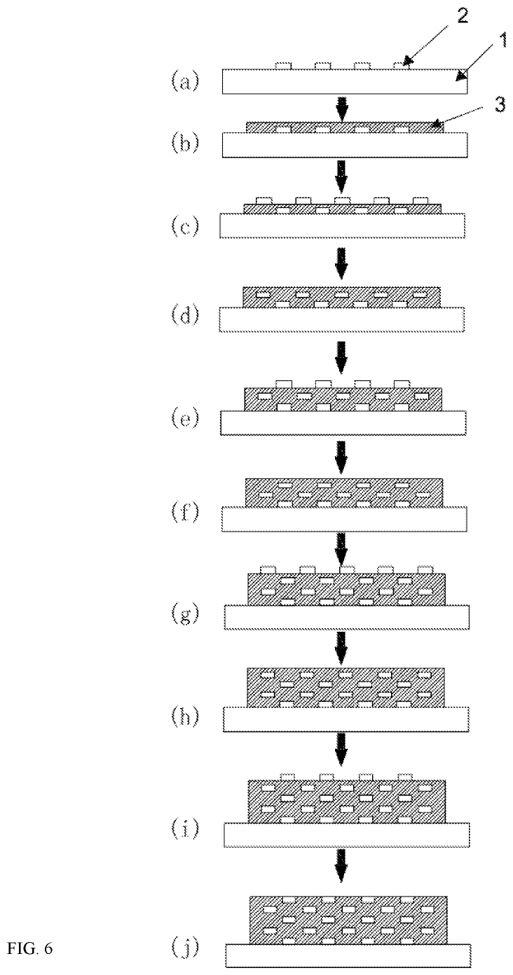

As shown in FIG. 1, the present embodiment provides a soft magnetic film iron core, mainly including an insulating substrate 1 and a soft magnet. The soft magnet is arranged on an upper surface of the insulating substrate 1. The soft magnet is made of a soft magnetic material 3, and is provided with multiple layers of hollowing-out grid networks stacked vertically therein.

Each layer of the hollowing-out grid network includes several rows and several columns of grid cavities. The grid cavities in the same layer of hollowing-out grid network are staggered in rows and columns, that is, any two adjacent rows of the grid cavities are staggered, and any two adjacent columns of the grid cavities are staggered. The grid cavities in any two adjacent layers of the hollowing-out grid networks are staggered and complementary. Each of the grid cavities is filled with an insulator. The material of the soft magnet, that is, the soft magnetic material 3 is preferably a sputtered soft magnetic material, such as a permalloy (Ni0.8Fe0.2). The material of the insulator is preferably PI 2, and the material of the insulating substrate 1 preferably adopts a silicon wafer with a silicon dioxide insulating layer to support the structure of the whole film iron core.

In the present embodiment, the foregoing soft magnet is preferably a square soft magnet, that is, the soft magnet is in the shape of a cuboid or a cube as a whole, and a lowermost hollowing-out grid network in the square soft magnet is closest to the upper surface of the insulating substrate 1. Each of the grid cavities is located inside the square soft magnet, that is, there is no grid cavity at the edge of the square soft magnet, and the outside of the whole square soft magnet is covered by the soft magnetic material 3.

In the present embodiment, the grid cavities in all odd-numbered layers of the hollowing-out grid networks from bottom to top in the soft magnet have a same distribution structure, and the grid cavities in all even-numbered layers of the hollowing-out grid networks have a same distribution structure.

In the present embodiment, each of the grid cavities is preferably a square grid cavity, and any two of the square grid cavities have a same size. The same size specifically means that each square grid cavity has the same length, width, and height.

In the present embodiment, in any odd-numbered layer of the hollowing-out grid network, the grid cavities are generally distributed in odd-numbered rows and odd-numbered columns, such as 7, 9, or 11 rows, and 15, 17, or 19 columns, with various arrangements, such as 7 rows and 15 columns, 7 rows and 17 columns, 9 rows and 17 columns, and 9 rows and 19 columns, which may be adaptively adjusted according to the size of the square soft magnet and grid cavity. In any even-numbered layer of the hollowing-out grid network, the grid cavities are also generally distributed in odd-numbered rows and odd-numbered columns, such as 7, 9, or 11 rows, and 15, 17, or 19 columns, with various arrangements, such as 7 rows and 15 columns, 7 rows and 17 columns, 9 rows and 17 columns, and 9 rows and 19 columns, which may be adaptively adjusted according to the size of the square soft magnet and grid cavity.

In the present embodiment, the above square soft magnet has a length, width, and height of 2,000-5,000 μm, 1,000-3,000 μm, and 5-50 μm respectively. Any one of the square grid cavities has a length, width, and height of 40-200 μm, 40-200 μm, and 0.5-3 μm respectively. The grid cavities in each layer of the hollowing-out grid network have a row spacing and a column spacing both of 20-100 μm.

As a preferred embodiment, as shown in FIG. 1, in any odd-numbered layer of the hollowing-out grid network, the grid cavities are distributed in 9 rows and 17 columns and have the same row spacing and column spacing. Numbers of the grid cavities in the 9 rows of grid cavities are 9, 8, 9, 8, 9, 8, 9, 8, and 9 respectively, and the grid cavities between any two adjacent rows of the grid cavities are staggered. Correspondingly, as shown in FIG. 4, preferably, in any even-numbered layer of the hollowing-out grid network, the grid cavities are also distributed in 9 rows and 17 columns and have the same row spacing and column spacing, numbers of the grid cavities in the 9 rows of grid cavities are 8, 9, 8, 9, 8, 9, 8, 9, and 8 respectively, and the grid cavities between any two adjacent rows of the grid cavities are staggered. For the hollowing-out grid networks arranged according to the above rules, the positions of the filled grid cavities of any two adjacent odd-numbered layers of hollowing-out grid networks and even-numbered layers of hollowing-out grid networks are complementary. After the odd-numbered and even-numbered layers of hollowing-out grid networks are overlapped, the two layers of PI filled square girds are complementary to each other, and a 9×17 array layout can be formed. In practical operation, the number of odd-numbered and even-numbered layers of hollowing-out grid networks in the iron core and the number, size, and arrangement of the grid cavities in each layer are not limited to the above examples, and can be adjusted according to different external parameter requirements. For example, the grid cavities in each layer of hollowing-out grid network are distributed in 9 rows and 19 columns.

Further, in the present embodiment, the square soft magnet has a length, width, and height of preferably 4,500 μm, 2,000 μm, and 12 μm respectively. Any one of the square grid cavities has a length, width, and height of preferably 180 μm, 180 μm, and 2 μm respectively. In practical operation, the height direction of the square grid cavity is consistent with the height direction of the square soft magnet.

Furthermore, the grid cavities in each layer of the hollowing-out grid network have a row spacing and a column spacing of preferably 60 μm. Taking the above-mentioned hollowing-out grid network distributed in 9 rows and 17 columns as an example, any two adjacent rows of grid cavities have a spacing of 60 μm, and any two adjacent columns of grid cavities also have a spacing of 60 μm.

The above-mentioned soft magnetic film iron core provided in the present embodiment is specifically a film iron core that has low saturation magnetic induction and coercivity and can be processed by the MEMS standard process. The film iron core is divided into a structure of multilayer staggered grid networks as a whole by opening a grid cavity in the soft magnet, and the portions without the grid cavity provided are formed by sputtering the soft magnetic material, the grid cavities have the insulating PI filled therein. The grid cavities filled with PI are evenly distributed, every two adjacent layers of grid cavities are spaced by a certain thickness of sputtered soft magnetic material, and the grid cavities in the odd-numbered layers and the grid cavities in the even-numbered layers are located in staggered arrangement with respect to each other, showing a complementary distribution. The above film iron core adopting a structure of multilayer staggered grid networks according to the present embodiment has excellent performance, facilitates to limit the size of the magnetic domain, and promotes uniform saturation of the iron core, thereby effectively reducing saturation magnetic induction and coercivity of the iron core, and improving its soft magnetic properties. Compared with the film iron core in the prior art, the iron core with a structure of multilayer staggered grid networks can make the film iron core saturate under a smaller current, which can reduce the excitation current, thereby significantly reducing power consumption of the micro fluxgate, and improving sensitivity and reducing noise to a certain extent.

### Embodiment II

The present embodiment provides a preparation method for the soft magnetic film iron core in Embodiment I, which mainly includes the following steps S1 to S6.

In step S1, the upper surface of the insulating substrate 1 is subjected to a sputtering treatment to form a Cu seed layer.

In step S2, the Cu seed layer is spin-coated with the PI, and subsequently subjected to a pre-imidization treatment, and UV lithography and wet etching treatment by means of a mask for odd-numbered layer, to obtain a first layer of PI filled grid network. Then, an imidization is performed on the PI.

In step S3, sputtering is performed around and above the first layer of PI filled grid to form a first layer of the iron core and a permalloy layer between the first layer and a second layer of the iron core.

In step S4, the permalloy layer is spin-coated with PI, and subsequently subjected to pre-imidization treatment, and UV lithography and wet etching treatment by means of a mask for even-numbered layer to obtain a second layer of PI filled grid. Then, the imidization is performed on the PI.

In step S5, sputtering is performed around and above the second layer of PI filled grid to form a second layer of iron core and a permalloy layer between the second layer and a third layer of the iron core.

In step S6, step S2-step S3-step S4-step S5 or step S2-step S3-step S4-step S5-step S2-step S3 are repeated in order for one or more times until the whole soft magnet is prepared. When the step S2-step S3-step S4-step S5 are repeated in order for one or more times, what is finally formed is a soft magnet with a total of even-numbered layers of hollowing-out grid networks; while, when the step S2-step S3-step S4-step S5-step S2-step S3 are repeated in order for one or more times, what is finally formed is a soft magnet with a total of odd-numbered layers of hollowing-out grid networks.

As can be seen from the above, the preparation method for the soft magnetic film iron core provided by the present embodiment is mainly implemented by three steps of magnetron sputtering, UV lithography, and wet etching. The PI filled grid cavity (or called “filled square grid”) is mainly prepared by four steps of spin coating, pre-imidization, UV lithography, wet etching, and imidization.

The preparation method for the above soft magnetic film iron core in the present embodiment will be described in detail below with reference to specific examples. The soft magnetic film iron core to be prepared is provided with 5 layers of hollowing-out grid networks filled with insulators. The soft magnetic material 3 used in the soft magnet is a sputtered permalloy (Ni0.8Fe0.2). The overall shape of the soft magnet is a cuboid soft magnet with a length of 4,500 m, a width of 2,000 μm, and a thickness (height) of 12 μm. The PI filled grid cavity in the soft magnet is a 180 μm×180 m×2 μm cuboid, and the grid cavities in each layer of hollowing-out grid network are distributed in 9 rows and 17 columns with the row spacing and the column spacing of 60 μm. In the 9 rows of grid cavities in the odd-numbered layer of hollowing-out grid network, the numbers of grid cavities in respective rows are: 9, 8, 9, 8, 9, 8, 9, 8, and 9, and the positions of the grid cavities between every two adjacent rows are staggered. In the 9 rows of grid cavities in the even-numbered layer of hollowing-out grid network, the numbers of grid cavities in respective rows are: 8, 9, 8, 9, 8, 9, 8, 9, and 8, and the positions of the grid cavities between every two adjacent rows are staggered. The positions of the filled grid cavities of the odd-numbered layer and even-numbered layer are complementary, so that after the odd-numbered layer and even-numbered layer are overlapped, PI filled square grids in one of the two layers and PI filled square grids in the other layer are complementary to each other, and a 9×17 array layout can be formed. The permalloy layer between every two layers of iron cores has a thickness of 0.5 μm. The specific step-by-step production process of the soft magnetic film iron core with the above 5-layer hollowing-out grid network is as follows.

First, a silicon wafer with a crystal orientation of (100) and a thickness of 250 μm is adopted as the insulating substrate 1. Sulfuric acid and hydrogen peroxide in a ratio of 4:1 are used to remove organic pollutants on the silicon wafer. Then, the insulating substrate 1 is subjected to ultrasonic cleaning with deionized water (DI) to remove impurities on the surface of the insulating substrate 1. A SiO₂ insulating layer with a thickness of 300 nm is grown on the silicon insulating substrate 1 by thermal oxidation. A Cu seed layer with a thickness of 100 nm is sputtered by using a magnetron sputtering process.

After that, according to the step-by-step production process of the soft magnet shown in FIG. 6 (the black arrows in the figure denote the progress of the preparation steps), the following steps are performed in sequence.

In step a), the Cu seed layer is spin-coated with the PI, and is subsequently subjected to pre-imidization treatment (heating at 130° C. for 30 min), and UV lithography and wet etching treatment by means of a mask for odd-numbered layer of the iron core to obtain a first layer of PI filled grid of the iron core. Then, an imidization is performed on the PI (heating at 200° C. for 240 min).

In step b), a first layer of the iron core and the soft magnetic material 3 (i.e., a permalloy layer) between the first layer and a second layer of the iron core are prepared using the sputtering process.

In step c), the soft magnetic material 3 between the first layer and a second layer of the iron core is spin-coated with the PI, and is subsequently subjected to pre-imidization treatment, and UV lithography and wet etching treatment by means of a mask for even-numbered layer of the iron core to obtain a second layer of PI filled grid of the iron core. Then, the imidization is performed on PI.

In step d), a second layer of the iron core and the soft magnetic material 3 (i.e., the permalloy layer) between the second layer and a third layer of the iron core are prepared using the sputtering process.

In step e), the soft magnetic material 3 between the second layer and a third layer of the iron core is spin-coated with PI, and is subsequently subjected to pre-imidization treatment, and UV lithography and wet etching treatment by means of the mask for odd-numbered layer of the iron core to obtain a third layer of PI filled grid of the iron core. Then, the imidization is performed on PI.

In step f), a third layer of the iron core and the soft magnetic material 3 (i.e., the permalloy layer) between the third layer and a fourth layer of the iron core are prepared using the sputtering process.

In step g), the soft magnetic material 3 between the third layer and a fourth layer of the iron core is spin-coated with the PI, and is subsequently subjected to pre-imidization treatment, and UV lithography and wet etching treatment by means of the mask for even-numbered layer of the iron core to obtain a fourth layer of PI filled grid of the iron core, Then, imidization is performed on the PI.

In step h), a fourth layer of the iron core and the soft magnetic material 3 (i.e., the permalloy layer) between the fourth layer and a fifth layer of the iron core are prepared using the sputtering process.

In step i), the soft magnetic material 3 (i.e., the permalloy layer) between the fourth layer and a fifth layer is spin-coated with the PI, and is subsequently subjected to pre-imidization treatment, and UV lithography and wet etching treatment by the mask for odd-numbered layer of the iron core to obtain a fifth layer of PI filled grid of the iron core. Then, the imidization is performed on PI.

In step j), a fifth layer of soft magnetic material 3 (i.e., the permalloy layer) is prepared using the sputtering process.

It can be seen that the step-by-step production process of the above soft magnet is the preparation process of the soft magnet with 5 layers of hollowing-out grid networks filled with insulators, which is implemented by subsequently repeating step S2-step S3-step S4-step S5-step S2-step S3 for signal time, after the second layer and the soft magnetic material 3 between the second and third layers of the iron core are formed. The preparation method for the soft magnetic film iron core provided by the present disclosure adopts low-cost MEMS standard processes such as UV lithography, electroplating, and wet etching, which can realize standardized mass production of the iron core and reduce the processing cost without effecting the soft magnetic properties of the iron core.

### Embodiment III

The present embodiment provides a sensor, including the soft magnetic film iron core as described in Embodiment I. The sensor may be a micro-magnetic fluxgate sensor using the soft magnetic film iron core as a sensitive element, which can effectively reduce power consumption and improve sensitivity and reduce noise to a certain extent.

It should be noted that it is obvious to those skilled in the art that the present disclosure is not limited to the details of the above exemplary embodiments, and that the present disclosure can be implemented in other specific forms without departing from the spirit or basic features of the present disclosure. Therefore, the embodiments should be regarded as exemplary and non-limiting in every respect. The scope of the present disclosure is defined by the appended claims rather than the above description, therefore, all changes falling withe meaning and scope of equivalent elements of the claims should be included in the present disclosure, and any reference numerals in the claims should not be construed as a limitation to the claims involved.

Specific examples are used for illustration of the principles and implementations of the present disclosure. The description of the above embodiments is merely used to help understand the method and its core ideas of the present disclosure. In addition, those of ordinary skill in the art can make modifications in terms of specific implementations and scope of use according to the ideas of the present disclosure. In conclusion, the content of the present description shall not be construed as limitations to the present disclosure.

What is claimed is:

1. A soft magnetic film iron core, comprising:
an insulating substrate; and
a soft magnet, arranged on an upper surface of the insulating substrate, and provided with multiple layers of hollowing-out grid networks stacked vertically therein; each layer of the hollowing-out grid network comprising a plurality of rows and a plurality of columns of grid cavities, any two adjacent rows of the grid cavities being staggered, and any two adjacent columns of the grid cavities being staggered; the grid cavities in any two adjacent layers of the hollowing-out grid networks being staggered and complementary; and each of the grid cavities being filled with an insulator.

2. The soft magnetic film iron core according to claim 1, wherein the soft magnet is a square soft magnet, and any of the grid cavities is located in the square soft magnet.

3. The soft magnetic film iron core according to claim 2, wherein in the soft magnet, the grid cavities in all odd-numbered layers of the hollowing-out grid networks from bottom to top have a same distribution structure, and the grid cavities in all even-numbered layers of the hollowing-out grid networks have a same distribution structure.

4. The soft magnetic film iron core according to claim 3, wherein each of the grid cavities is a square grid cavity, and any two of the square grid cavities have a same size.

5. The soft magnetic film iron core according to claim 4, wherein in any odd-numbered layer of the hollowing-out grid network, the grid cavities are distributed in 7 rows, 9 rows, or 11 rows, and 15 columns, 17 columns, or 19 columns; and in any even-numbered layer of the hollowing-out grid network, the grid cavities are distributed in 7 rows, 9 rows, or 11 rows, and 15 columns, 17 columns, or 19 columns; and
the square soft magnet has a length, width, and height of 2,000-5,000 μm, 1,000-3,000 μm, and 5-50 μm respectively; any one of the square grid cavities has a length, width, and height of 40-200 μm, 40-200 μm, and 0.5-3 μm respectively; and the grid cavities in each layer of the hollowing-out grid network have a row spacing and a column spacing both of 20-100 μm.

6. The soft magnetic film iron core according to claim 5, wherein in any odd-numbered layer of the hollowing-out grid network, the grid cavities are distributed in 9 rows and 17 columns, numbers of the grid cavities in the 9 rows of grid cavities are 9, 8, 9, 8, 9, 8, 9, 8, and 9 respectively, and the grid cavities between any two adjacent rows of the grid cavities are staggered; and in any even-numbered layer of the hollowing-out grid network, the grid cavities are distributed in 9 rows and 17 columns, numbers of the grid cavities in the 9 rows of grid cavities are 8, 9, 8, 9, 8, 9, 8, 9, and 8 respectively, and the grid cavities between any two adjacent rows of the grid cavities are staggered; and
the square soft magnet has a length, width, and height of 4,500 μm, 2,000 μm, and 12 μm respectively; any one of the square grid cavities has a length, width, and height of 180 μm, 180 αm, and 2 μm respectively; and the grid cavities in each layer of the hollowing-out grid network have a row spacing and a column spacing both of 60 μm.

7. The soft magnetic film iron core according to claim 3, wherein the soft magnet is a permalloy soft magnet; the insulator is polyimide (PI); and the insulating substrate is a silicon wafer substrate with a silicon dioxide insulating layer.

8. The soft magnetic film iron core according to claim 4, wherein the soft magnet is a permalloy soft magnet; the insulator is polyimide (PI); and the insulating substrate is a silicon wafer substrate with a silicon dioxide insulating layer.

9. The soft magnetic film iron core according to claim 5, wherein the soft magnet is a permalloy soft magnet; the insulator is polyimide (PI); and the insulating substrate is a silicon wafer substrate with a silicon dioxide insulating layer.

10. The soft magnetic film iron core according to claim 6, wherein the soft magnet is a permalloy soft magnet; the insulator is polyimide (PI); and the insulating substrate is a silicon wafer substrate with a silicon dioxide insulating layer.

11. A preparation method for the soft magnetic film iron core according to claim 7, comprising:
S1, performing sputtering on the upper surface of the insulating substrate to form a Cu seed layer;
S2, spin-coating the PI on the Cu seed layer, subsequently performing pre-imidization treatment and performing ultraviolet (UV) lithography and wet etching treatment by means of a first mask of odd-numbered layer of the iron core to obtain a first layer of PI filled grid, and imidizing the PI;
S3, sputtering around and above the first layer of PI filled grid to form a first layer of the iron core and a permalloy layer between the first layer and a second layer of the iron core;
S4, spin-coating the PI on the permalloy layer between the first layer and a second layer of the iron core, subsequently performing pre-imidization treatment and UV lithography and wet etching treatment by a second mask for even-numbered layer of the iron core to obtain a second layer of PI filled grid, and imidizing the PI;
S5, sputtering around and above the second layer of PI filled grid to form a second layer of iron core and a permalloy layer between the second layer and a third layer of the iron core; and
S6, repeating step S2-step S3-step S4-step S5 or step S2-step S3-step S4-step S5-step S2-step S3 in order for one or more times until whole soft magnet is prepared.

12. A preparation method for the soft magnetic film iron core according to claim 8, comprising:
S1, performing sputtering on the upper surface of the insulating substrate to form a Cu seed layer;
S2, spin-coating the PI on the Cu seed layer, subsequently performing pre-imidization treatment and performing ultraviolet (UV) lithography and wet etching treatment by means of a first mask of odd-numbered layer of the iron core to obtain a first layer of PI filled grid, and imidizing the PI;
S3, sputtering around and above the first layer of PI filled grid to form a first layer of the iron core and a permalloy layer between the first layer and a second layer of the iron core;
S4, spin-coating the PI on the permalloy layer between the first layer and a second layer of the iron core, subsequently performing pre-imidization treatment and UV lithography and wet etching treatment by a second mask for even-numbered layer of the iron core to obtain a second layer of PI filled grid, and imidizing the PI;
S5, sputtering around and above the second layer of PI filled grid to form a second layer of iron core and a permalloy layer between the second layer and a third layer of the iron core; and
S6, repeating step S2-step S3-step S4-step S5 or step S2-step S3-step S4-step S5-step S2-step S3 in order for one or more times until whole soft magnet is prepared.

13. A preparation method for the soft magnetic film iron core according to claim 9, comprising:
S1, performing sputtering on the upper surface of the insulating substrate to form a Cu seed layer;
S2, spin-coating the PI on the Cu seed layer, subsequently performing pre-imidization treatment and performing ultraviolet (UV) lithography and wet etching treatment by means of a first mask of odd-numbered layer of the iron core to obtain a first layer of PI filled grid, and imidizing the PI;
S3, sputtering around and above the first layer of PI filled grid to form a first layer of the iron core and a permalloy layer between the first layer and a second layer of the iron core;
S4, spin-coating the PI on the permalloy layer between the first layer and a second layer of the iron core, subsequently performing pre-imidization treatment and UV lithography and wet etching treatment by a second mask for even-numbered layer of the iron core to obtain a second layer of PI filled grid, and imidizing the PI;
S5, sputtering around and above the second layer of PI filled grid to form a second layer of iron core and a permalloy layer between the second layer and a third layer of the iron core; and
S6, repeating step S2-step S3-step S4-step S5 or step S2-step S3-step S4-step S5-step S2-step S3 in order for one or more times until whole soft magnet is prepared.

14. A preparation method for the soft magnetic film iron core according to claim 10, comprising:
S1, performing sputtering on the upper surface of the insulating substrate to form a Cu seed layer;
S2, spin-coating the PI on the Cu seed layer, subsequently performing pre-imidization treatment and performing ultraviolet (UV) lithography and wet etching treatment by means of a first mask of odd-numbered layer of the iron core to obtain a first layer of PI filled grid, and imidizing the PI;
S3, sputtering around and above the first layer of PI filled grid to form a first layer of the iron core and a permalloy layer between the first layer and a second layer of the iron core;
S4, spin-coating the PI on the permalloy layer between the first layer and a second layer of the iron core, subsequently performing pre-imidization treatment and UV lithography and wet etching treatment by a second mask for even-numbered layer of the iron core to obtain a second layer of PI filled grid, and imidizing the PI;
S5, sputtering around and above the second layer of PI filled grid to form a second layer of iron core and a permalloy layer between the second layer and a third layer of the iron core; and
S6, repeating step S2-step S3-step S4-step S5 or step S2-step S3-step S4-step S5-step S2-step S3 in order for one or more times until whole soft magnet is prepared.

15. The preparation method for the soft magnetic film iron core according to claim 11, wherein the permalloy layer is sputtered by a magnetron sputtering process; and the permalloy layer between every two adjacent layers of iron cores has a thickness of 0.5 μm.

16. The preparation method for the soft magnetic film iron core according to claim 12, wherein the permalloy layer is sputtered by a magnetron sputtering process; and the permalloy layer between every two adjacent layers of iron cores has a thickness of 0.5 μm.

17. The preparation method for the soft magnetic film iron core according to claim 13, wherein the permalloy layer is sputtered by a magnetron sputtering process; and the permalloy layer between every two adjacent layers of iron cores has a thickness of 0.5 μm.

18. The preparation method for the soft magnetic film iron core according to claim 14, wherein the permalloy layer is sputtered by a magnetron sputtering process; and the permalloy layer between every two adjacent layers of iron cores has a thickness of 0.5 μm.

19. A sensor, comprising the soft magnetic film iron core according to claim 1.
